(19) United States
(12) Patent Application Publication
(10) Pub. No.: US 2007/0295972 A1
(43) Pub. Date: Dec. 27, 2007

(54) LIGHT EMITTING DIODE MODULE

(76) Inventors: Shau-Yu Tsai, Taipei City (TW); Chih-Lin Wang, Hsinchu City (TW); Jyh-Haur Huang, Ping-Tung County (TW); Ci-Guang Peng, Chiayi City (TW)

Correspondence Address: NORTH AMERICA INTELLECTUAL PROPERTY CORPORATION, P.O. BOX 506, MERRIFIELD, VA, 22116, US

(21) Appl. No.: 11/535,495

(22) Filed: Sep. 27, 2006

(30) Foreign Application Priority Data
Jun. 27, 2006 (TW) 095123131

(51) Int. Cl. H01L 33/00

(52) U.S. Cl. 257/88

(57) ABSTRACT

A light emitting diode module is disclosed. The light emitting diode module includes a substrate, a plurality of light emitting diodes, and a plurality of lenses. The light emitting diodes are disposed on the substrate, and the lenses are disposed on the substrate and covering the light emitting diodes, in which each of the lenses includes a curved surface corresponding to each of the light emitting diodes.

### BACKGROUND OF THE INVENTION

1. Field of the Invention

The invention relates to a light emitting diode module.

2. Description of the Prior Art

Liquid crystal displays are commonly utilized in various electronic products including cell phones, PDAs, and notebook computers. As the market demand for large-scale display panels continues to increase, liquid crystal displays having advantages such as small size and light weight have become widely popular. Due to the fact that the liquid crystal display itself does not illuminate, a backlight unit has to be installed under the liquid crystal display to provide a light source for the liquid crystal display.

Backlight units are commonly divided into two major categories: side-emitting type and direct type. Side-emitting type backlight units often utilize a light guide plate to convert light sources in a form of dots or lines into a plane light source for the liquid crystal panel. Due to their low cost, side-emitting type backlight units are widely used in small size liquid crystal display panels. Direct type backlight units on the other hand, do not include a light guide plate, and thus are more widely utilized in large scale liquid crystal display panels. Additionally, the plane light source provided for the liquid crystal display is divided into two types: one arranging a plurality of cold cathode fluorescent lamps (CCFL) or external electrode fluorescent lamps in a parallel manner, and the other arranging a plurality of dot light source, such as a plurality of light emitting diodes arranged in a manner of a matrix. Since light emitting diodes have the advantage of high color saturation, being mercury-free, having long life expectancy, a low temperature, and have the ability to adjust color temperature through a driving current, they have been commonly utilized in backlight units.

Please refer to FIG. 1. FIG. 1 is a perspective diagram illustrating a conventional light emitting diode module 10. As shown in FIG. 1, the light emitting diode module 10 includes a substrate 12, a plurality of light emitting diodes 14 disposed on the substrate 12, a lead frame 16 connected to the light emitting diodes 14, a plurality of leads (not shown) electrically connecting to the light emitting diodes 14 and the lead frame 16, and a lens 18 disposed on a surface of the light emitting diodes 14. The substrate 12 can be a packaging base, such as a carrier composed of PPA resin, and the light emitting diodes 14 can be selected from red light emitting diodes, green light emitting diodes, blue light emitting diodes, white light emitting diodes, or light emitting diodes of other colors.

Typically, the lens 18 disposed on the light emitting diodes 14 is composed of epoxy or silicone, in which the lens also includes a curved surface 20, as shown in FIG. 1. In general, lights are generated by the light emitting diodes 14 and then refracted to the ambient environment through the lens 18. Due to the fact that the conventional light emitting diode module 10 utilizes a design of having a plurality of light emitting diodes sharing a single curved surface, lights generated by light emitting diodes 14 of different characteristics are likely to cause an uneven distribution after bouncing off the curved surface 20 of the lens 18, thereby affecting the light-mixing ability of the light emitting diode module 10.

### SUMMARY OF THE INVENTION

It is therefore an objective of the present invention to provide a light emitting diode module to solve the aforementioned problem.

The present invention discloses a light emitting diode module. The light emitting diode includes a substrate, a plurality of light emitting diodes disposed on the substrate, and a plurality of lenses disposed on the substrate and covering the light emitting diodes, in which each of the lenses includes a curved surface corresponding to each of the light emitting diodes.

Preferably, the present invention disposes a corresponding lens on top of each light emitting diode, utilizes the curvature variation of each curved surface of the lens and the reversed cone structure of each lens to control the dispersion of lights emitting at small angles, and adjusts the inclined angle of each sidewall of the lens to control and collect the lights emitting at large angles from the light emitting diodes. The present invention also utilizes the vertex variation of the reversed cone structure disposed on the curved surface of each lens to effectively disperse the stronger lights produced by the light emitting diodes, thereby preventing lights from concentrating in the central area of the lens and preventing the problem of bright spots. In other words, by adjusting the curved surface, inclined sidewall, and reversed cone structure of each lens, the present invention is able to significantly extend the candela distribution and expand the viewing angle of the light emitting diodes, and increase the distance between each of the light emitting diodes, thereby reducing the amount of light emitting diodes utilized in a light emitting diode module and the overall fabrication cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective diagram illustrating a conventional light emitting diode module.

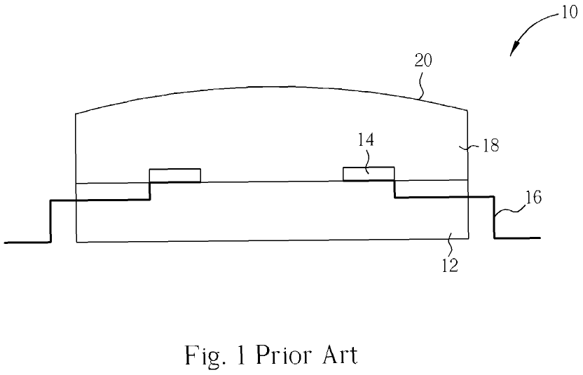

FIG. 2 is a top-view diagram illustrating a light emitting diode module according to a preferred embodiment of the present invention.

FIG. 3 is a side-view diagram of the light emitting diode module from FIG. 2.

FIG. 4 is a perspective diagram illustrating a light emitting diode module according to an embodiment of the present invention.

FIG. 5 is a perspective diagram illustrating a light emitting diode module according to an embodiment of the present invention.

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

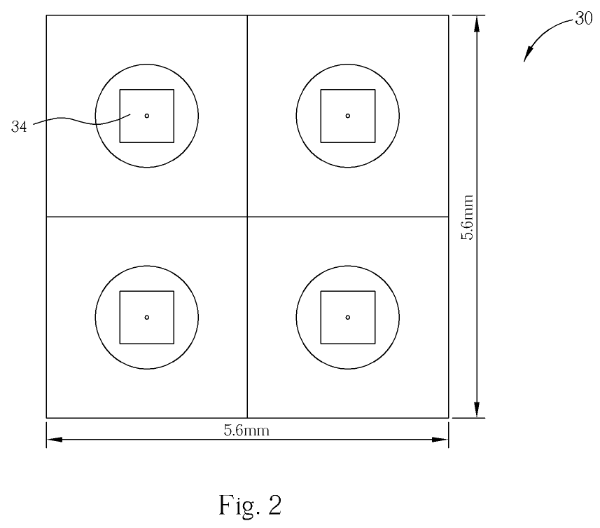

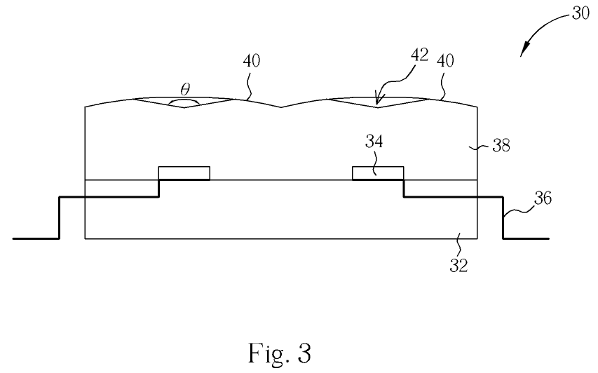

Please refer to FIG. 2 and FIG. 3. FIG. 2 is a top-view diagram illustrating a light emitting diode module 30 according to a preferred embodiment of the present invention. FIG. 3 is a side-view diagram of the light emitting diode module 30 from FIG. 2. As shown in FIG. 2, the light emitting diode module 30 is composed of four light emitting diodes 34 arranged in a manner of a matrix, in which the light emitting diodes 34 can be red light emitting diodes, green light emitting diodes, blue light emitting diodes, white light emitting diodes, or light emitting diodes of other colors. Additionally, the amount, color, and arrangement of the light emitting diodes 34 can be adjusted according to the design of the product, and not limited thereto.

As shown in FIG. 3, the light emitting diode module 30 includes a substrate 32, a plurality of light emitting diodes 34 disposed on the substrate 32, a lead frame 36 connected to the light emitting diodes 34, a plurality of leads (not shown) electrically connecting to the light emitting diodes 34 and the lead frame 36, and a plurality of lenses 38 disposed on a surface of the light emitting diodes 34. The substrate 32 can be a heat dissipating substrate, a conductive substrate, a circuit board, or a packaging base, such as a carrier composed of PPA resin.

The lenses 38 disposed on the light emitting diodes 34 are composed of transparent materials including epoxy or silicone, in which each lens 38 may include a convex surface 40 or a concave surface (not shown). According to the preferred embodiment of the present invention, each curved surface 40 can have a same or different curvature radius, in which the height of each lens 38 is less than the curvature radius of each curved surface 40. For instance, if the length of each side of the light emitting diode module 30 is 5.6 microns, and the curvature radius of the curved surface 40 is 20 microns, the height of the lens 38 will be 1.2 microns.

The top of each lens 38 also includes a cavity 42, in which the cavity 42 is formed on each curved surface 40 and corresponding to each light emitting diode 34. In the present embodiment, the cavity 42 is a reversed cone structure, in which the vertex angle of the reversed cone structure includes a range between 150 degrees to 180 degrees. However, each reversed cone structure may also include a different vertex angle, which is also within the scope of the present invention.

As shown in the figure, the present invention primarily disposes a plurality of lenses 38 on the light emitting diodes 34, in which the curved surface 40 of each lens 38 is disposed corresponding to each of the light emitting diodes 34. Nevertheless, the present invention can also dispose a compound lens (not shown) having a plurality of sub-lenses directly on the light emitting diodes 34, such that each sub-lens of the compound lens is placed corresponding to each light emitting diode, thereby achieving the same effect as the aforementioned method.

It should be noted that the inclined angle of the sidewall of each lens could be adjusted to control the dispersion and gathering of lights emitting at large angles, and the curved surface and the reversed cone structure of each lens can be utilized to optimize and control the dispersion of lights emitting at small angles according to different properties of each light emitting diode. In other words, the present invention is able to utilize the curvature variation of each curved surface and the reversed cone structure disposed on each curved surface to extend the candela distribution and expand the viewing angle of the light emitting diodes, thereby preventing the conventional problem of bright spots.

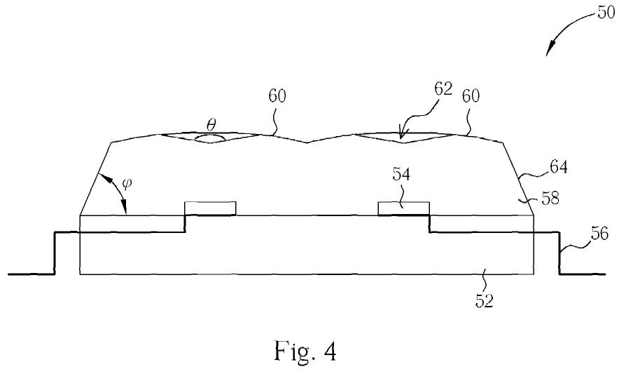

Please refer to FIG. 4. FIG. 4 is a perspective diagram illustrating a light emitting diode module 50 according to an embodiment of the present invention. As shown in FIG. 4, the light emitting diode module 50 includes a substrate 52, a plurality of light emitting diodes 54 disposed on the substrate 52, a lead frame 56 connected to the light emitting diodes 54, a plurality of leads (not shown) electrically connecting to the light emitting diodes 54 and the lead frame 56, and a plurality of lenses 58 disposed on a surface of the light emitting diodes 54. The substrate 52 can be a heat dissipating substrate, a conductive substrate, a circuit board, or a packaging base, such as a carrier composed of PPA resin, and the light emitting diodes 54 can be red light emitting diodes, green light emitting diodes, blue light emitting diodes, white light emitting diodes, or light emitting diodes of other colors.

The lenses 58 disposed on the light emitting diodes 54 are composed of transparent materials including epoxy or silicone, in which each lens 58 may include a convex surface 60 or a concave surface (not shown). According to the preferred embodiment of the present invention, each curved surface 60 can have a same or different curvature radius, in which the height of each lens 58 is less than the curvature radius of each curved surface 60.

The top of each lens 58 also includes a cavity 62, in which the cavity 62 is formed on each curved surface 50 and corresponding to each light emitting diode 54. In the present embodiment, the cavity 62 is a reversed cone structure, in which the vertex angle of the reversed cone structure includes a range between 150 degrees to 180 degrees. However, each reversed cone structure may also include a different vertex angle, which is also within the scope of the present invention.

Similar to the previous embodiment, the present embodiment principally disposes a plurality of lenses 58 on the light emitting diodes 54, in which the curved surface 60 of each lens 58 is disposed corresponding to each of the light emitting diodes 54. Additionally, the present invention can dispose a compound lens (not shown) having a plurality of sub-lenses directly on the light emitting diodes 54, such that each sub-lens of the compound lens is placed corresponding to each light emitting diode, thereby achieving the same effect as the aforementioned method.

In contrast to the previous embodiment, each lens 58 further includes at least one inclined sidewall 64, in which an included angle φ formed between the surface of the substrate 52 and the inclined sidewall 64 includes a range between 20 degrees to 90 degrees. Hence, the present embodiment not only utilizes the curved surface 60 and the reversed cone structure to adjust the candela distribution of light emitting diodes having different properties, but also utilizes the inclined sidewalls 64 to create more angular variation for different light emitting diodes, thereby maximizing the distribution and gathering of lights emitting at large angles.

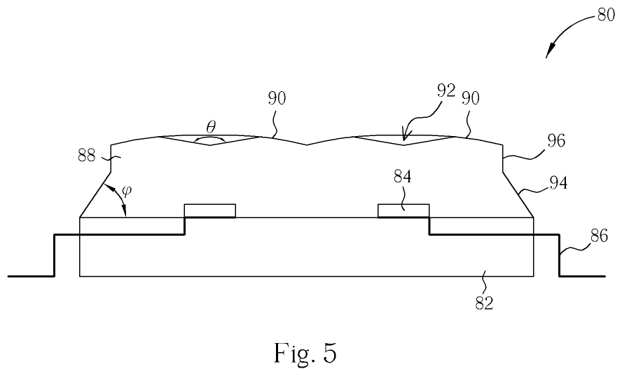

Please refer to FIG. 5. FIG. 5 is a perspective diagram illustrating a light emitting diode module 80 according to an embodiment of the present invention. As shown in FIG. 5, the light emitting diode module 80 includes a substrate 82, a plurality of light emitting diodes 84 disposed on the substrate 82, a lead frame 86 connected to the light emitting diodes 84, a plurality of leads (not shown) electrically connecting to the light emitting diodes 84 and the lead frame 86, and a plurality of lenses 88 disposed on a surface of the light emitting diodes 84. The substrate 82 can be a heat dissipating substrate, a conductive substrate, a circuit board, or a packaging base, such as a carrier composed of PPA resin, and the light emitting diodes 84 can be red light emitting diodes, green light emitting diodes, blue light emitting diodes, white light emitting diodes, or light emitting diodes of other colors.

The lenses 88 disposed on the light emitting diodes 84 are composed of transparent materials including epoxy or silicone, in which each lens 88 may include a convex surface 90 or a concave surface (not shown). According to the preferred embodiment of the present invention, each curved surface 90 can have a same or different curvature radius, in which the height of each lens 88 is less than the curvature radius of each curved surface 90.

The top of each lens 88 also includes a cavity 92, in which the cavity 92 is formed on each curved surface 90 and corresponding to each light emitting diode 84. In the present embodiment, the cavity 92 is a reversed cone structure, in which the vertex angle of the reversed cone structure includes a range between 150 degrees to 180 degrees. However, each reversed cone structure may also include a different vertex angle, which is also within the scope of the present invention.

Similar to the previous embodiment, the present embodiment principally disposes a plurality of lenses 88 on the light emitting diodes 84, in which the curved surface 90 of each lens 88 is disposed corresponding to each of the light emitting diodes 84. Additionally, the present invention can dispose a compound lens (not shown) having a plurality of sub-lenses directly on the light emitting diodes 84, such that each sub-lens of the compound lens is placed corresponding to each light emitting diode, thereby achieving the same effect as the aforementioned method.

In contrast to the previous embodiment, each lens 88 of the present embodiment not only includes at least one inclined sidewall 94, but also a vertical sidewall 96 connected to the inclined sidewall 94 and the top of the lens 88, in which an included angle φ formed between the surface of the substrate 82 and the inclined sidewall 94 has a range between 20 degrees to 90 degrees. Hence, the present embodiment not only utilizes the curved surface 90 and the reversed cone structure of each lens 88 to adjust the candela distribution of light emitting diodes having different properties, but also utilizes the inclined sidewalls 94 and the vertical sidewall 96 to create more angular variation for different light emitting diodes, thereby maximizing the distribution and gathering of lights emitting at large angles.

In contrast to the conventional light emitting diode modules, the present invention disposes a corresponding lens on top of each light emitting diode, and adjusts the curvature variation of each curved surface of the lens and the inclined angle of each sidewall of the lens to control and collect lights emitting at large angle from the light emitting diodes. The present invention also utilizes the vertex variation of the reversed cone structure disposed on the curved surface of each lens to effectively disperse the stronger lights produced by the light emitting diodes, thereby preventing lights from concentrating in the central area of the lens and preventing the problem of bright spots. In other words, by adjusting the curved surface, inclined sidewall, and reversed cone structure of each lens, the present invention is able to significantly extend the candela distribution and expand the viewing angle of the light emitting diodes, and increase the distance between each of the light emitting diodes, thereby reducing the amount of light emitting diodes utilized in a light emitting diode module and the overall fabrication cost. Additionally, the curved surface and the vertex of the reversed cone structure can be further adjusted according to the property of each light emitting diode. Moreover, in contrast to the conventional design of utilizing a single lens for a plurality of light emitting diodes, each lens of the present invention is specifically designed for each of the light emitting diodes. Ultimately, the uniformity, energy distribution and the mixing ability of the light emitting diode module can be significantly enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting diode module, comprising:
a substrate;
a plurality of light emitting diodes disposed on the substrate; and
a plurality of lenses, disposed on the substrate, covering the light emitting diodes, wherein each of the lenses comprises a curved surface corresponding to each of the light emitting diodes.

2. The light emitting diode module of claim 1, wherein the light emitting diodes are selected from the group consisting of red light emitting diodes, green light emitting diodes, blue light emitting diodes, and white light emitting diodes.

3. The light emitting diode module of claim 1, wherein the substrate comprises a heat dissipating substrate, a conductive substrate, or a circuit board.

4. The light emitting diode module of claim 1, wherein the height of each lens is less than the curvature radius of the curved surface of each lens.

5. The light emitting diode module of claim 1, wherein the curvature radius of each curved surface is identical.

6. The light emitting diode module of claim 1, wherein the curvature radius of each curved surface is different.

7. The light emitting diode module of claim 1, wherein each lens comprises a cavity disposed on the curved surface corresponding to each light emitting diode.

8. The light emitting diode module of claim 7, wherein the cavity comprises a reversed cone structure, wherein the vertex angle of the reversed cone structure ranges from 150 degrees to 180 degrees.

9. The light emitting diode module of claim 1, wherein each lens comprises an inclined sidewall having an included angle between the surface of the substrate and the inclined sidewall, wherein the included angle ranges from 20 degrees to 90 degrees.

10. The light emitting diode module of claim 1, wherein each lens comprises epoxy or silicone.

11. The light emitting diode module of claim 1, wherein the curved surface comprises a convex surface.

12. The light emitting diode module of claim 1, wherein the curved surface comprises a concave surface.

13. A light emitting diode module, comprising:
a substrate;
a plurality of light emitting diodes disposed on the substrate; and
a lens disposed on the substrate and covering the light emitting diodes, the lens comprising a plurality of sub-lenses, wherein each sub-lens comprises a curved surface corresponding to each of the light emitting diodes.

14. The light emitting diode module of claim 13, wherein the light emitting diodes are red light emitting diodes, green light emitting diodes, blue light emitting diodes, white light emitting diodes, or combinations thereof.

15. The light emitting diode module of claim 13, wherein the substrate comprises a heat dissipating substrate, a conductive substrate, or a circuit board.

16. The light emitting diode module of claim 13, wherein the height of the lens is less than the curvature radius of the curved surface of the lens.

17. The light emitting diode module of claim 13, wherein the curvature radius of each curved surface is identical.

18. The light emitting diode module of claim 13, wherein the curvature radius of each curved surface is different.

19. The light emitting diode module of claim 13, wherein each curved surface comprises a reversed cone cavity, wherein the vertex angle of the reversed cone cavity ranges from 150 degrees to 180 degrees.

20. The light emitting diode module of claim 13, wherein each lens comprises an inclined sidewall having an included angle between the surface of the substrate and the inclined sidewall, wherein the included angle ranges from 20 degrees to 90 degrees.

21. The light emitting diode module of claim 13, wherein each lens comprises epoxy or silicone.

22. The light emitting diode module of claim 13, wherein the curved surface comprises a convex surface.

23. The light emitting diode module of claim 13, wherein the curved surface comprises a concave surface.
